(19) United States
(12) Patent Application Publication
(10) Pub. No.: US 2026/0068671 A1
(43) Pub. Date: Mar. 5, 2026

(54) SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Wensen Hung, Hsinchu County (TW); Tsung-Yu Chen, Hsinchu City (TW)

(73) Assignee: Taiwan Semiconductor Manufacturing Company, Ltd., Hsinchu (TW)

(21) Appl. No.: 18/817,187

(22) Filed: Aug. 27, 2024

(51) Int. Cl. H01L 23/46; H01L 21/48; H01L 23/00; H01L 23/31; H01L 23/367; H01L 23/373; H01L 25/00; H01L 25/065

(52) U.S. Cl. CPC H01L 23/46

(57) ABSTRACT

A semiconductor package includes a substrate, a package structure, and a lid structure. The package structure is bonded over the substrate. The lid structure is bonded over the substrate and thermally coupled to the package structure, wherein the lid structure includes a fluid chamber and a plurality of spring members disposed in the fluid chamber, wherein each of the plurality of spring members is connected between an upper plate and a lower plate of the fluid chamber.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 illustrates a cross sectional views of intermediate stages in the manufacturing of a semiconductor package according to some embodiments of the present disclosure.

FIG. 7 to FIG. 10 illustrates a cross sectional views of intermediate stages in the manufacturing of a semiconductor package according to some embodiments of the present disclosure.

FIG. 11 illustrates a perspective top view of the semiconductor package according to some embodiments of the present disclosure.

FIG. 12 illustrates a cross sectional view of the semiconductor package according to some embodiments of the present disclosure.

FIG. 13 illustrates a perspective top view of the semiconductor package according to some embodiments of the present disclosure.

FIG. 14 and FIG. 15 illustrate schematic views of different fin structure of applied to semiconductor packages according to some embodiments of the present disclosure.

FIG. 16 illustrates a cross sectional view of the semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

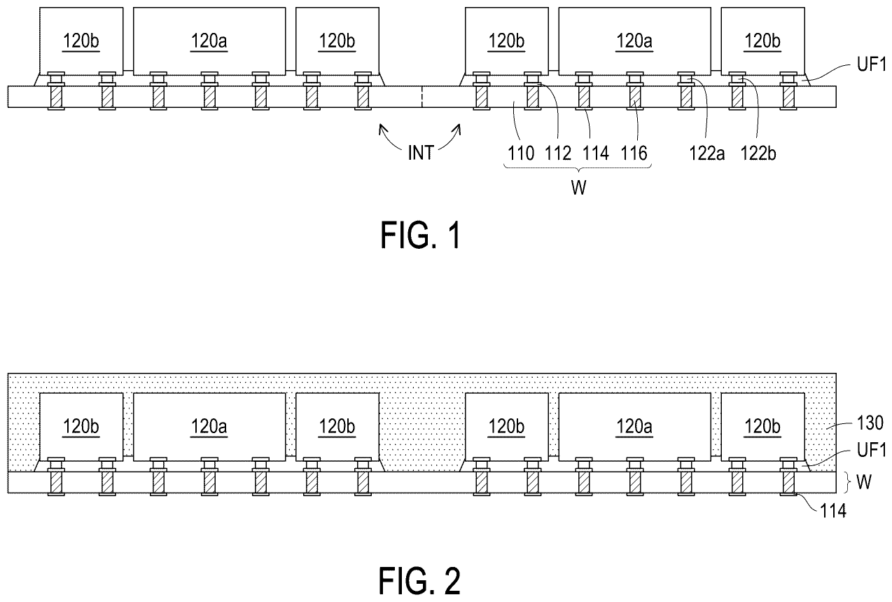

FIG. 1 to FIG. 6 illustrates a cross sectional views of intermediate stages in the manufacturing of a semiconductor package according to some embodiments of the present disclosure. Referring to FIG. 1, an interconnect structure (e.g., an interposer wafer) W including a plurality of interconnect structures INT arranged in array is provided. The interposer wafer W may be a silicon interposer wafer including multiple silicon interposers or other suitable semiconductor interposer wafer. The interposer wafer W may include a substrate 110, bump pads 112 disposed on an upper surface of the substrate 110, bump pads 114 disposed on a lower surface of the substrate 110, and through semiconductor vias (TSVs) 116 penetrating through the substrate 110, wherein the bump pads 112 are electrically connected to the bump pads 114 through the TSVs 116. The interposer wafer W may be a semiconductor substrate such as a silicon substrate. The interposer wafer W may also be formed of another semiconductor material such as silicon germanium, silicon carbon, or the like. In accordance with some embodiments, active devices such as transistors (not separately illustrated) are formed at a surface of the interposer wafer W. Passive devices (not separately illustrated) such as resistors and/or capacitors may also be formed in the interposer wafer W. In accordance with alternative embodiments of the present disclosure, the interposer wafer W may be a semiconductor substrate or a dielectric substrate, and the respective interposer wafer W may not include active devices therein. In accordance with these embodiments, the interposer wafer W may, or may not, include passive devices formed therein.

The TSVs 116 may be formed to extend from the top surface of the interposer wafer W into the interposer wafer W. The TSVs 116 may be referred to as through-substrate vias or through-silicon vias in embodiments in which the interposer wafer W is a silicon substrate. In some embodiments, the interposer wafer W may include an interconnect structure (not separately illustrated) formed over the substrate 110 which is used to electrically connect to the integrated circuit devices, if any, and the TSVs 116. The interconnect structure may include a plurality of dielectric layers, metal lines formed in the dielectric layers, and vias formed between, and interconnecting, the overlying and underlying metal lines. In accordance with some embodiments, the dielectric layers may be formed of silicon oxide, silicon nitride, silicon carbide, silicon oxynitride, combinations thereof, and/or multi-layers thereof. Alternatively, the dielectric layers may include one or more low-k dielectric layers having low dielectric constants (k values). The k values of the low-k dielectric materials in the dielectric layers may be lower than about 3.0 or lower than about 2.5, for example.

At least one semiconductor die is provided over and boned to a surface of the interconnect structure (i.e. the interposer wafer W). In the embodiment, semiconductor dies 120a and semiconductor dies 120b are illustrated herein, but not limited thereto. The semiconductor dies 120a and semiconductor dies 120b are electrically connected to the interconnect structures INT of the interposer wafer W. In some embodiments, the semiconductor dies 120a and semiconductor dies 120b are electrically connected to the bump pads 112 of the interposer wafer W through conductive bumps 122a and conductive bumps 122b. The conductive bumps 122a are located between the semiconductor dies 120a and the bump pads 112, and the conductive bumps 122b are located between the semiconductor dies 120b and the bump pads 112. In some embodiments, the conductive bumps 122a may be formed on the semiconductor dies 120a before the semiconductor dies 120a are mounted on the interposer wafer W, and the conductive bumps 122b may be formed on the semiconductor dies 120b before the semiconductor dies 120b are mounted on the interposer wafer W. The conductive bumps 122a may be formed through a wafer-level bumping process performed on semiconductor wafers including the semiconductor dies 120a arranged in array, and the conductive bumps 122b may be formed through another wafer-level bumping process performed on semiconductor wafers including the semiconductor dies 120b arranged in array. In some embodiments, the semiconductor dies 120a includes logic dies, System-on-Chip (SoC) dies or other suitable semiconductor dies, and the semiconductor dies 120b includes High Bandwidth Memory (HBM) cubes each having stacked memory dies or other suitable semiconductor dies.

In some embodiments, the semiconductor dies 120a may include a high-power consuming die disposed between two semiconductor dies 120b, which may be a low-power consuming dies. The high-power consuming die and the low-power consuming dies may be die stacks and may be referred to as chips. The high-power consuming die consumes a relatively high amount of power and, therefore, generates a relatively large amount of heat compared to the lower-power consuming dies. For example, the high-power consuming die may consume from about 100 W to about 1,000 W of power and the low-power consuming dies may consume from about 10 W to about 100 W of power. A ratio of the power consumed by the high-power consuming die to the power consumed by the low-power consuming dies may be from about 10 to about 30, such as about 16. The high-power consuming die may be a processor, such as a central processing unit (CPU), a graphics processing unit (GPU), or the like. The low-power consuming dies may be memory dies such as high bandwidth memory (HBM), memory cubes, memory stacks, or the like. While the present embodiment illustrates one high-power consuming die (e.g., semiconductor dies 120a) and two low-power consuming dies (e.g., semiconductor dies 120b) in a package, other embodiments may include any number of high-power consuming dies and/or low-power consuming dies.

In some embodiments, the conductive bumps 122a and the conductive bumps 122b include micro bumps. The conductive bumps 122a and the conductive bumps 122b may each include a copper (Cu) pillar covered by a nickel (Ni) cap, and the nickel (Ni) cap may be electrically connected to the bump pads 112 through solder material. For example, the solder material includes Sn—Ag solder material or other suitable solder material.

After the semiconductor dies 120a and the semiconductor dies 120b are mounted on and electrically connected to the interposer wafer W through the conductive bumps 122a and the conductive bumps 122b, underfills UF1 are formed over the interposer wafer W to fill gaps between the semiconductor dies 120a and the interposer wafer W as well as gaps between the semiconductor dies 120b and the interposer wafer W. The conductive bumps 122a and the conductive bumps 122b are laterally encapsulated and protected by the underfills UF1 such that damage of the conductive bumps 122a and the conductive bumps 122b resulted from coefficient of thermal expansion (CTE) mismatch between the interposer wafer W and the semiconductor dies 120a and 120b may be prevented. Accordingly, reliability of the conductive bumps 122a and the conductive bumps 122b may be improved.

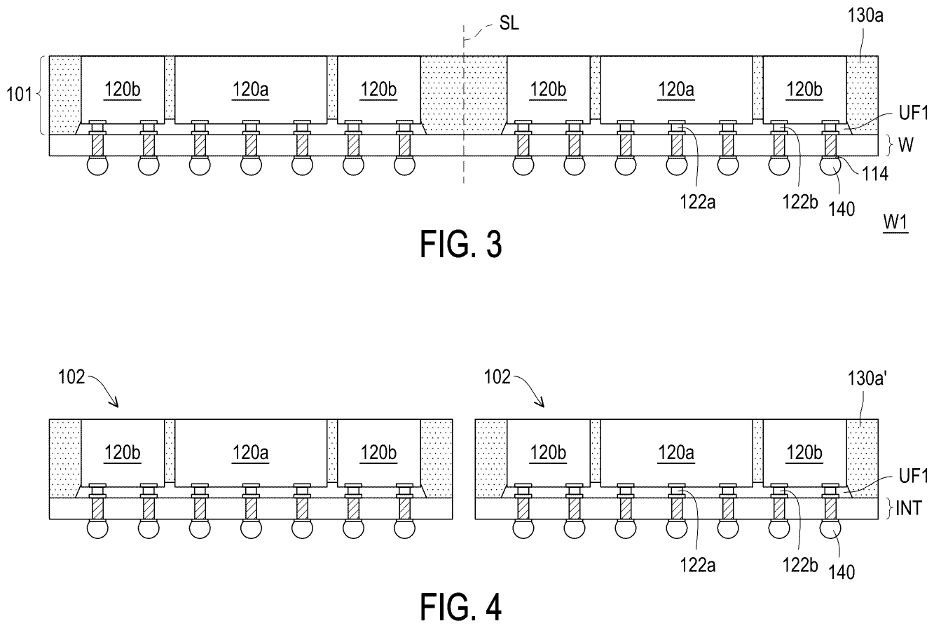

Referring to FIG. 2 and FIG. 3, the semiconductor dies 120a and 120b are encapsulated with an encapsulating material 130. The encapsulating material 130 is formed over the interposer wafer W to cover the semiconductor dies 120a and the semiconductor dies 120b. The encapsulating material 130 may be formed by an over-molding process or a deposition process followed by a removal process. In some embodiments, an encapsulating material 130 such as epoxy resin is formed on the interposer wafer W to cover the back surfaces and sidewalls of the semiconductor dies 120a and 120b through an over-molding process, and a grinding process, a chemical mechanical polishing (CMP) process or other suitable removal process is then performed to remove portions of the epoxy resin until the back surfaces of the semiconductor dies 120a and 120b are revealed. In some alternative embodiments, an encapsulating material 130 such as tetraethoxysilane (TEOS) formed oxide is formed on the interposer wafer W to cover back surfaces and sidewalls of the semiconductor dies 120a and 120b through a chemical vapor deposition (CVD) process, and a grinding process, a CMP process or other suitable removal process is then performed to remove portions of the TEOS formed oxide until the back surfaces of the semiconductor dies 120a and 120b are revealed. After performing the above-mentioned removal process, as illustrated in FIG. 3, an encapsulating material 130a is formed to laterally encapsulate the semiconductor dies 120a and 120b, and the top surface of the encapsulating material 130a is substantially leveled with the back surfaces of the semiconductor dies 120a and 120b.

In some embodiments, during the removal process of the encapsulating material 130, the encapsulating material 130, the semiconductor dies 120a and the semiconductor dies 120b are partially removed such that the thickness of the semiconductor dies 120a and 120b is reduced. At this point, an encapsulated semiconductor device 101 as shown in FIG. 3 that includes the semiconductor dies 120a and 120b laterally encapsulated by the encapsulating material 130a is formed. The encapsulated semiconductor device 101 is bonded over the interposer wafer W.

A wafer-level bumping process may be performed such that conductive bumps 140 are formed over bump pads 114 of the interposer wafer W. In some embodiments, the wafer-level bumping process for forming the conductive bumps 140 is performed before formation of the encapsulating material 130a. In some alternative embodiments, the wafer-level bumping process for forming the conductive bumps 140 is performed after formation of the encapsulating material 130a.

After forming the encapsulating material 130a and the conductive bumps 140, a reconstructed wafer W1 including the interposer wafer W, the semiconductor dies 120a, the semiconductor dies 120b, the underfills UF1, the encapsulating material 130a, and the conductive bumps 140 is formed.

Referring to FIG. 3 and FIG. 4, a wafer saw process is then performed along scribe lines SL such that the reconstructed wafer W1 is singulated into a plurality of package structures 102. The package structures 102 may each include an interconnect structure INT, an encapsulated semiconductor device 101 including at least one semiconductor die 120a, 120b encapsulated by the encapsulating material 130a′ and bonded over the interconnect structure INT, a plurality of conductive bumps 122a, 122b, an underfill UF1, and a plurality of conductive bumps 140. The conductive bumps 122a are electrically connected between the semiconductor die 120a and the interconnect structure INT. The conductive bumps 122b are electrically connected between the semiconductor die 120b and the interconnect structure INT. The underfill UF1 laterally encapsulates the conductive bumps 122a and 122b. The underfill UF1 may further cover sidewalls of the semiconductor dies 120a and 120b. The encapsulating material 130a′ laterally encapsulates the semiconductor dies 120a and 120b, wherein sidewalls of the encapsulating material 130a′ are substantially aligned with sidewalls of the interconnect structure INT. Furthermore, the conductive bumps 122a and 122b are disposed on a surface (e.g., an upper surface) of the interconnect structure INT, and the conductive bumps 140 are disposed on another surface (e.g., a lower surface) of the interconnect structure INT.

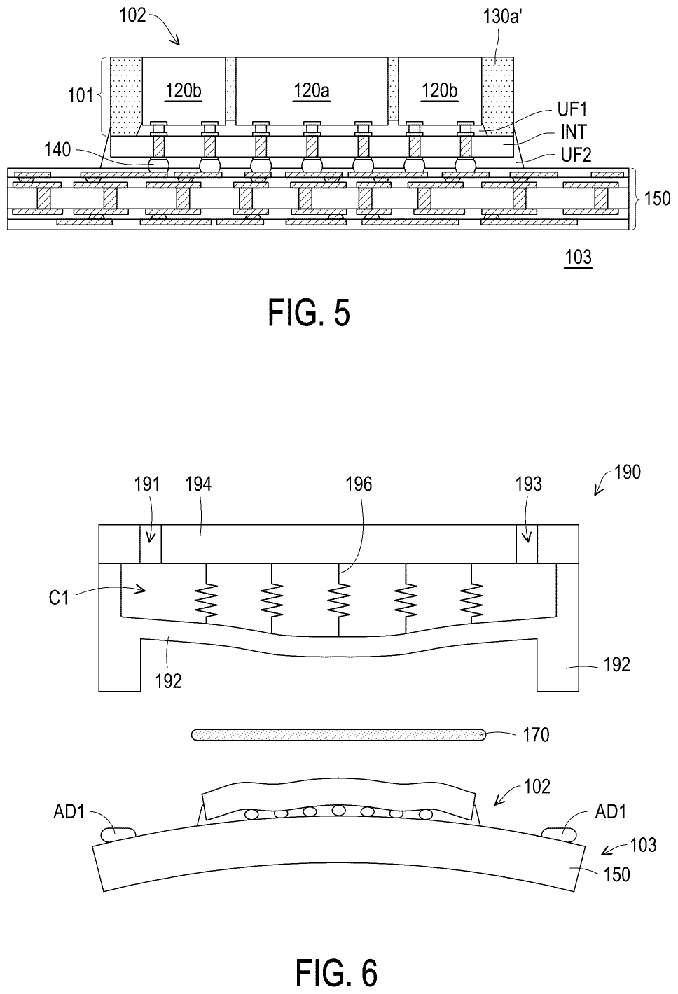

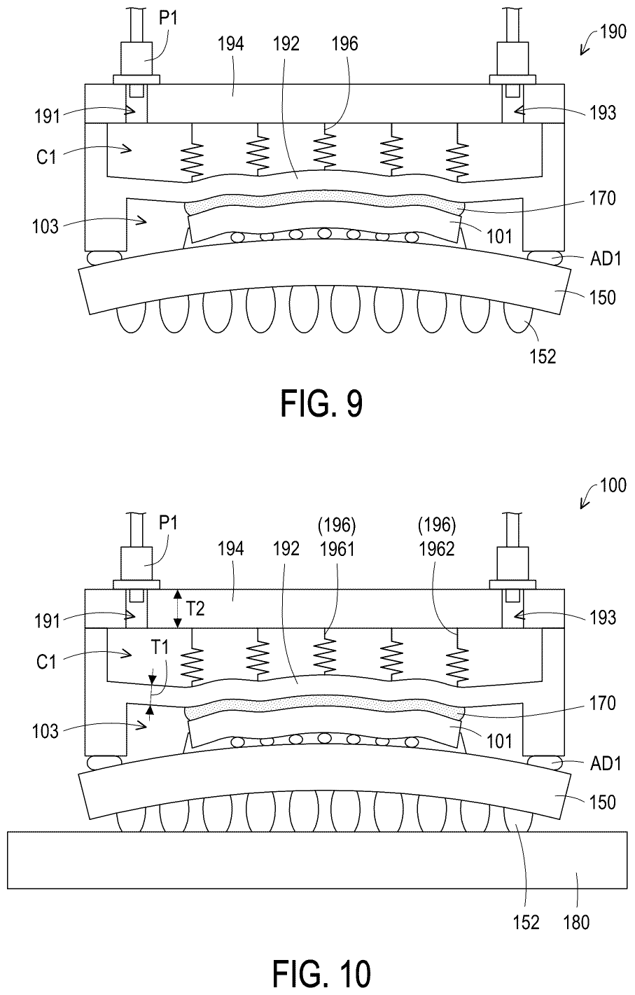

Referring to FIG. 5, a substrate 150 is provided. In some embodiments, the substrate 150 includes a dielectric core layer, build-up or laminated dielectric layers stacked over opposite surfaces of the dielectric core layer, conductive wiring layers embedded in the build-up or laminated dielectric layers, conductive vias penetrating through the dielectric core layer and the build-up or laminated dielectric layers. The substrate 150 may be a package substrate, which may be a printed circuit board (PCB) or the like. In some embodiments, the substrate 150 may include through-vias, active devices, passive devices, and the like. The substrate 150 may further include conductive pads formed at the upper and lower surfaces of the substrate 150, such that a plurality of conductive connectors (e.g. the conductive connectors 152 shown in FIG. 9) may be coupled to conductive pads at the top surface of the substrate 150.

Then, at least one of the package structures 102 singulated from the reconstructed wafer W1 illustrated in FIG. 3 may be picked-up and placed on an upper surface of the substrate 150. The package structure 102 is electrically connected to the conductive wirings of the substrate 150 through the conductive bumps 140. After the package structure 102 is bonded over the substrate 150, an underfill UF2 may be formed to fill a gap between the substrate 150 and the interconnect structure INT of the package structure 102. The conductive bumps 140 are laterally encapsulated and protected by the underfill UF2 such that damage of the conductive bumps 140 resulted from CTE mismatch between the interconnect structure INT and the substrate 150 may be prevented. Accordingly, reliability of the conductive bumps 140 may be improved.

In some embodiments, the underfill UF2 not only fills the gap between the substrate 150 and the interconnect structure INT of the package structure 102, but also covers sidewalls of the package structure 102. As illustrated in FIG. 5, the underfill UF2 not only fills the gap between the substrate 150 and the interconnect structure INT of the package structure 102, but also covers sidewalls of the interconnect structure INT and sidewalls of the encapsulating material 130a.

After the package structure 102 is bonded over the substrate 150, a chip on wafer on substrate (CoWoS) package 103 is formed. The CoWoS package 103 includes a substrate 150, an interconnect structure INT bonded over and electrically connected to the substrate 150, semiconductor dies 120a, 120b disposed on and electrically connected to the interconnect structure INT, an encapsulating material 130a′ disposed on the interconnect structure INT. The semiconductor dies 120a, 120b are laterally encapsulated by the encapsulating material 130a′. In some embodiments, the CoWoS package 103 further includes an underfill UF2 disposed between the interconnect structure INT and the substrate 150.

Referring to FIG. 6, it is noted that the packager structure 102 shown in FIG. 5 is illustrated as a block hereinafter for purpose of simplicity. Detail description of same or similar features may be omitted, and the same or similar reference numbers denote the same or like components. Then, a thermal interface material (TIM) 170 is applied to cover a top surface of the package structure 102 and an adhesive AD1 is applied to a peripheral region of the substrate 150 that surrounds the package structure 102. The thermal interface material 170 may cover the top surface of the package structure 102 and a portion of the top surface of the encapsulating material insulating encapsulation 160, and the adhesive 180 may cover the rest portion of the top surface of the insulating encapsulation 160. The material of the thermal interface material 170 may include metallic TIM, such as indium (In) sheet or film, indium foil, indium solder, silver (Ag) paste, silver alloy or combination thereof. For the embodiment of the thermal interface material 170 being metallic TIM, a backside metallization layer may be formed over the top surface of the package structure 102 for better bonding the metallic TIM. The material of the backside metallization layer may include copper (Cu), titanium (Ti), nickel-vanadium (NiV), nickel (Ni), silver (Ag), gold (Au), the like, or any combination thereof, with an overall thickness ranges from 0.6 μm to 0.65 μm.

In some embodiments, the thermal interface material 170 may also be polymer-based TIM with thermal conductive fillers. Applicable thermal conductive filler materials may include aluminum oxide, boron nitride, aluminum nitride, aluminum, copper, silver, indium, a combination thereof, or the like. The thermal interface material 170 may include film-based or sheet-based material such as sheet with synthesized carbon nano-tube (CNT) structure integrated into the sheet, thermal conductive sheet with vertically oriented graphite fillers or the like. The thermal interface material 170 may be formed of liquid metal or liquid pad or other metallic material or combination thereof. The material of the adhesive 180 may include thermally conductive adhesive or epoxy-based adhesive or the like.

The adhesive AD1 may be an epoxy, a silicon resin, a glue, or the like. The adhesive AD1 may have a better adhering ability than the thermal interface material 170. The adhesive AD1 may have a thermal conductivity from about 1 W/m·K to about 3 W/m·K, lower than about 0.5 W/m·K, or the like. The adhesive AD1 may be positioned so as to allow a heat dissipating feature such as a lid structure 190 shown in FIG. 6 to be attached around the package structure 102. Thus, in some embodiments, the adhesive AD1 may be disposed around the perimeter of, or even encircle, the package structure 102.

A lid structure 190 is then provided over and bonded to the thermal interface material 170 and the adhesive 180. The lid structure 190 is thermally coupled to and in contact with the top surfaces of the package structure 102 through the thermal interface material 170, and the lid structure 190 is adhered with the top surface of the substrate 150 through the adhesive 180. The lid structure 190 may be formed from a material having a high thermal conductivity such as copper, aluminum, cobalt, copper coated with nickel, stainless steel, tungsten, silver diamond, aluminum silicon carbide, combinations thereof, or the like. Furthermore, the lid structure 190 may serve and function as a heat sink. In some embodiments, the lid structure 190 may be a metal coated with another metal, such as gold. The lid structure 190 may be formed of a material having a thermal conductivity from about 100 W/m·K to about 400 W/m·K, such as about 400 W/m·K. The lid structure 190 covers and surrounds the package structure 102. In some embodiments, the lid structure 190 is a single continuous material. In other embodiments, the lid structure 190 may include multiple pieces that may be the same or different materials.

In some embodiments, the lid structure 190 may include a fluid chamber C1 and a plurality of spring members 196 disposed in the fluid chamber C1 in an array manner. The lid structure 190 may include a lower plate 192 and an upper plate 194 bonded to each other to jointly define the fluid chamber C1 therein. Each of the spring members 196 is connected between the upper plate 194 and the lower plate 192 of the lid structure 190.

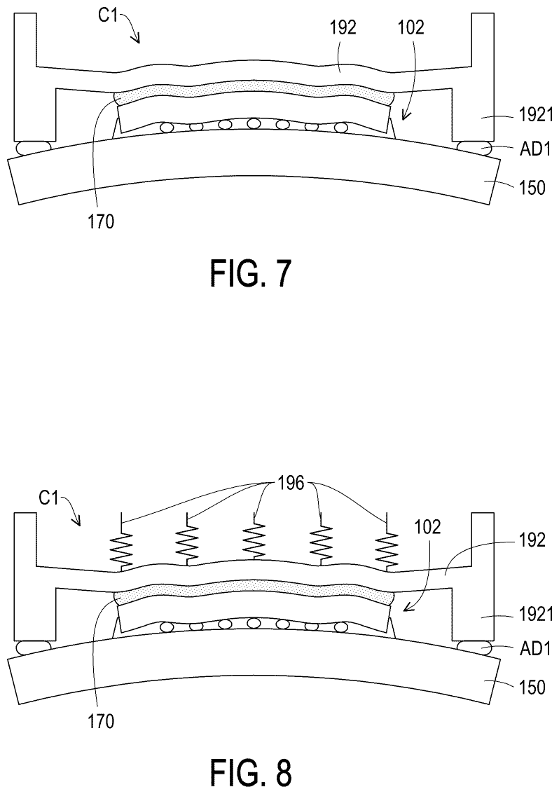

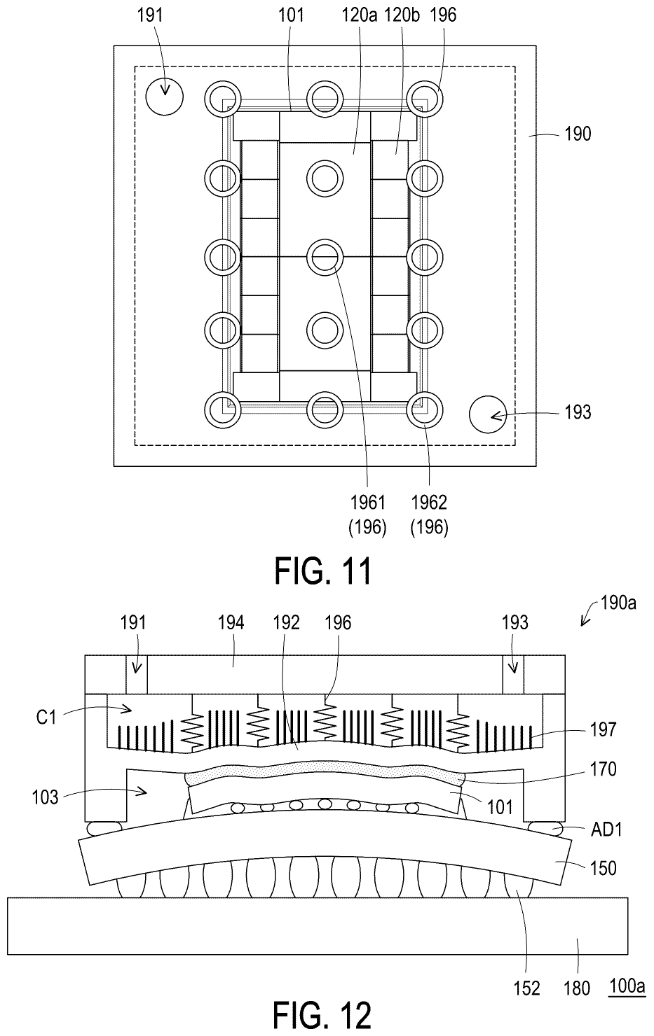

FIG. 7 to FIG. 10 illustrates a cross sectional views of intermediate stages in the manufacturing of a semiconductor package according to some embodiments of the present disclosure. In the present embodiment, one of the possible process of assembling and bonding the lid structure 190 over the substrate 150 is illustrated, but the disclosure is not limited thereto. Firstly, referring to FIG. 7, the lower plate 192 is bonded to the package structure 102 through the thermal interface material 170, and bonded to the substrate 150 through adhesive AD1. In some embodiments, the lower plate 192 defines a lower part of the fluid chamber C1, and the lower plate 192 further includes a sidewall portion 1921 connecting the fluid chamber C1 and bonded to the substrate 150 through the adhesive AD1. Then, referring to FIG. 8 and FIG. 11, a plurality of spring members 196 are disposed over the lower plate 192. In some embodiments, the spring members 196 are arranged within the fluid chamber C1 in an array manner as shown in FIG. 11. In some embodiments, each of the spring members 196 at least partially overlaps with the encapsulated semiconductor device 101 from a top view. Then, referring to FIG. 9, the upper plate 194 is bonded over the lower plate 192 and the plurality of spring members 196, such that the upper plate 194 and the lower plate 192 jointly define the fluid chamber C1. Next, a plurality of conductive connectors 152 are formed on a lower surface of the substrate 150 and electrically connected to the bottommost conductive wiring layer of the substrate 150.

In some embodiments, the lid structure 190 further includes an inlet 191 and an outlet 193, which are in fluid communication with the fluid chamber C1. A cooling fluid may flow through pipe P1 and enter the fluid chamber C1 through the inlet 191, and leaves the fluid chamber C1 through the outlet 193 for dissipating the heat generated from the package structure 102 that is conducted to the lid structure 190.

With now reference to FIG. 10, the structure of the CoWoS package 103 with the lid structure 190 is then bonded to the package substrate 180 and electrically connected to the package substrate 180 through the conductive connectors 152. In some embodiments, an underfill (not shown) may be provided to fill a gap between the CoWoS package 103 and the package substrate 180 to encapsulate the conductive connectors 152. The conductive connectors 152 are laterally encapsulated and protected by the underfills such that damage of the conductive connectors 152 resulted from coefficient of thermal expansion (CTE) mismatch between the CoWoS package 103 and the package substrate 180 may be prevented. Accordingly, reliability of the conductive connectors 152 may be improved. Accordingly, a semiconductor package 100 shown in FIG. 10 is substantially formed.

Due to differences in the coefficient of thermal expansion (CTE) of various structural layers, the CoWoS package 103 suffer from severe warpage issue, which causes poor thermal coupling between the CoWoS package 103 and the lid structure 190 or even causes delamination between the CoWoS package 103 and the lid structure 190. To improve the bonding and the thermal coupling between the CoWoS package 103 and the lid structure 190, the spring members 196 are disposed in the fluid chamber C1 in an array manner, so that the lower plate 192 is pressed against (in contact with) the thermal interface material 170 through the spring members 196. Accordingly, the lower plate 192 would be relatively more flexible (softer) than the upper plate 194 so as to be able to deform (conform) with the warpage profile of the CoWoS package 103. That is, a stiffness of the upper plate 194 is substantially greater than a stiffness of the lower plate 192. For example, the stiffness of the upper plate 194 is substantially 2 to10 times greater than the stiffness of the lower plate 192. In some embodiments, the lower plate 192 is thinner than the upper plate 194 so as to be able to deform (conform) with the warpage profile of the CoWoS package 103. That is, a thickness T2 of the upper plate 194 is substantially greater than a thickness T1 of the lower plate 192. For example, the thickness T2 of the upper plate 194 ranges from about 2 mm to about 4 mm, the thickness T1 of the lower plate 192 ranges from about 0.5 mm to about 2 mm, and the thickness T2 of the upper plate 194 is about 2 to 5 times greater than a thickness of the lower plate 192.

In some embodiments, the spring members 196 may include a plurality of first spring members 1961 disposed in a center region of the fluid chamber C1 and a plurality of second spring members 1962 surrounding the first spring members 1961. A spring constant of one of the first spring members 1961 may be different from a spring constant of one of the second spring members 1962 according to different needs. For example, in one embodiment, the spring constant of the first spring members 1961 at the center region of the fluid chamber C1 may be substantially greater than the spring constant of the second spring members 1962 at a peripheral region of the fluid chamber C1, so that the pressure applied to the lower plate 192 is greater at the center region of the CoWoS package 103 where the heat dissipation efficiency is highly required. In other embodiment, the spring constant of the second spring members 1962 at the peripheral region may be substantially greater than the spring constant of the first spring members 1961 at the center region, so that the pressure applied to the lower plate 192 is greater at the peripheral region of the CoWoS package 103 where the warpage is more severe. The disclosure is not limited thereto.

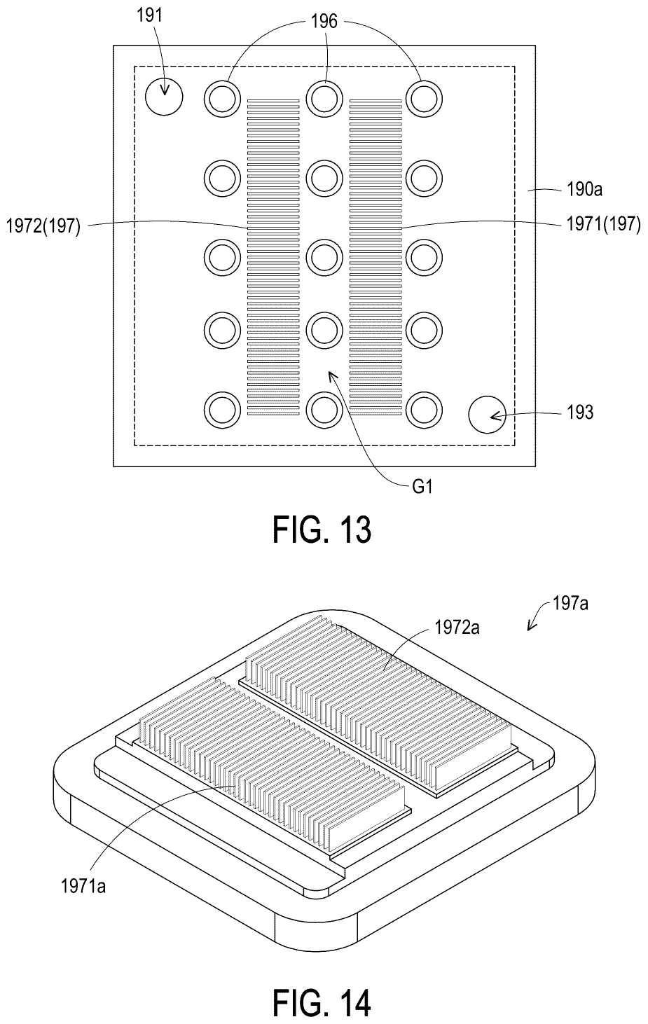

FIG. 12 illustrates a cross sectional view of the semiconductor package according to some embodiments of the present disclosure. FIG. 13 illustrates a perspective top view of the semiconductor package according to some embodiments of the present disclosure. It is noted that the semiconductor package 100a shown in FIG. 12 to FIG. 13 contains many features same as or similar to the semiconductor packages disclosed in the previous embodiments. For purpose of clarity and simplicity, detail description of same or similar features may be omitted, and the same or similar reference numbers denote the same or like components.

Referring to FIG. 12 and FIG. 13, the lid structure 190 further includes a plurality of fin structures 197 disposed in the fluid chamber C1. By disposing a large number of fin structures 197 in the lid structure 190, the fluid chamber C1 may exhibit a much greater surface area for thermal exchange and circulation of the cooling fluid flowing in the fluid chamber C1, so as to further improve the heat dissipation efficiency. In some embodiments, the fin structures 197 may include a plurality of fin sets 1971, 1972 (two sets are illustrated but the disclosure is not limited thereto), and each of the fin sets 1971, 1972 includes a plurality of fins. A gap G1 is maintained between adjacent two of the fin sets 1971, 1972A, and the spring members 196 are disposed around the fin sets 1971, 1972A and disposed in the gap G1. The fin structure 197 may be integrally formed with the lower plate 192 of the lid structure 190. That is, there is no interface between the fin structure 197 and the lower plate 192, but the disclosure is not limited thereto. In other embodiments, the fin structure 197 may be fixed to the lower plate 192 through welding, soldering, adhesive attaching, or any suitable method.

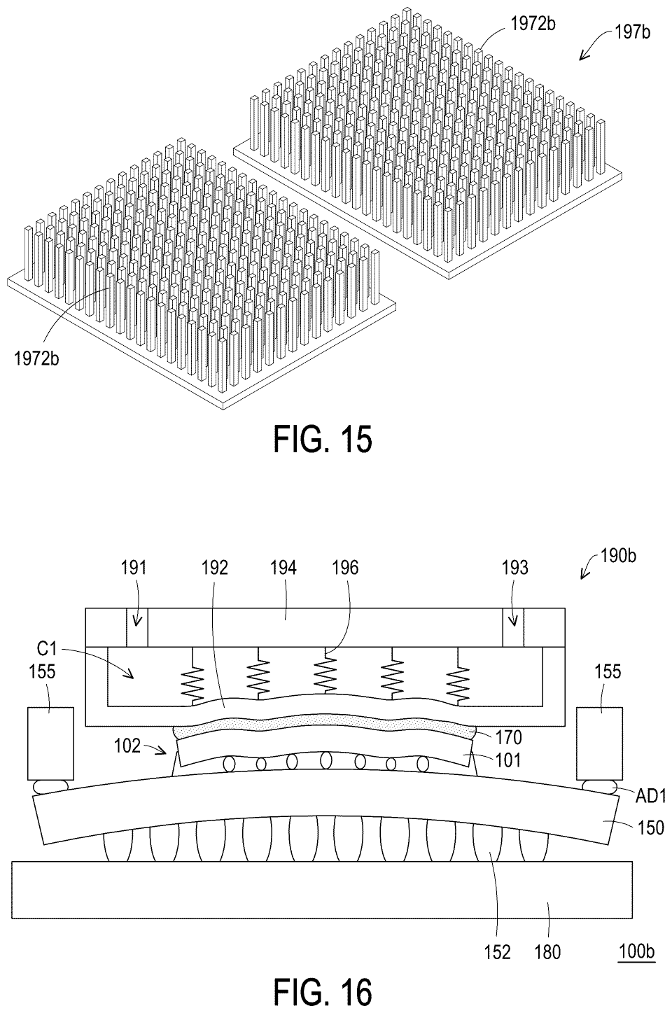

FIG. 14 and FIG. 15 illustrate schematic views of different fin structure of applied to semiconductor packages according to some embodiments of the present disclosure. Referring to FIG. 14, in some embodiments, the fin structure 197a includes a plurality of fin sets 1971a, 1972a, and each of the fin sets 1971a, 1972a may include a plurality of micro skived fins, which may be in the form of an array of straight or flared fins. Referring to FIG. 15, in other embodiments, the fin structure 197b includes a plurality of fin sets 1971b, 1972b, and each of the fin sets 1971b, 1972b may include a plurality of pin fins, which may be in the form of a matrix of geometrically shaped pins. A cross section of each of the pin fins may be in the shape of square, hexagon, rectangle, circle, or the like, and rows or columns of the pin fins may be arranged in line with one another or staggered from one another. The embodiments are merely for illustration, and the disclosure does not limit types or shapes of the fin structure.

FIG. 16 illustrates a cross sectional view of the semiconductor package according to some embodiments of the present disclosure. It is noted that the semiconductor package 100a shown in FIG. 12 to FIG. 13 contains many features same as or similar to the semiconductor packages disclosed in the previous embodiments. For purpose of clarity and simplicity, detail description of same or similar features may be omitted, and the same or similar reference numbers denote the same or like components.

Referring to FIG. 16, in the present embodiment, the lid structure 190b is bonded to the top surface of the encapsulated semiconductor device 101 through the thermal interface material 170 without being bonded to the substrate 180. In the embodiment, the semiconductor package 100b further includes a ring structure 155, which is bonded over the substrate 150 through the adhesive AD1 and surrounds the package structure 102. The ring structure 155 may be configured to constrain the underfill UF2, to compensate the stress on the substrate 150 induced by other components, and/or compensate CTE mismatch between the substrate 150 and other components.

As used herein, the term “ring structure” refers to a structure that substantially confines a space. In some embodiments, the ring structure may be a continuous ring structure which has a continuous perimeter. In some embodiments, the ring structure may include several segmented pieces. In some embodiments, the ring structure may be made of conductive material, and may be grounded or supplied with a potential. In other embodiments, the ring structure may be made of insulating material.

In some embodiments, the ring structure 155 is an independent component that is spaced apart from the lid structure 190b. The ring structure 155 is adjacent to a perimeter of the substrate 150, and may include a continuous ring structure substantially aligned along the perimeter of the substrate 150. In some embodiments, the shape of the ring structure 155 may include a rectangular ring, but not limited thereto. In some embodiments, the ring structure 155 may be a conductive ring structure such as a metal ring structure or the like. In some embodiments, the ring structure 155 may be grounded or supplied with a potential. In some embodiments, the ring structure 155 is attached to the surface of the substrate 150 with the adhesive AD1. In some embodiments, the adhesive AD1 may include a thermal-curable adhesive or a photo-curable adhesive, and a thermal curing or a photo curing may be performed to enhance adhesion between the ring structure 155 and the substrate 150. In some embodiments, the ring structure 155 is configured to enhance robustness of the edge of the substrate 150. In some embodiments, the ring structure 155 is configured to shield electromagnetic interference (EMI). In some embodiments, the ring structure 155 is configured to provide heat dissipation for the package structure 103. In some embodiments, the ring structure 155 is configured to compensate CTE mismatch between the underfill UF2 and the substrate 150, and to compensate stress on the substrate 150, such that coplanarity (COP) of the substrate 150 is reduced. As a result, warpage of the substrate 150 can be alleviated, underfill crack risk can be reduced, and cold joint and bump crack of the conductive bumps 140 between the package structure 102 and the substrate 150 can be alleviated or eliminated. The ring structure 155 can also be referred to as “stiffener ring” for providing extra support to the semiconductor package 100b thus reducing warpage.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a substrate, a package structure bonded over the substrate, and a lid structure bonded over the substrate and thermally coupled to the package structure, wherein the lid structure includes a fluid chamber and a plurality of spring members disposed in the fluid chamber, wherein each of the plurality of spring members is connected between an upper plate and a lower plate of the lid structure. In one embodiment, a stiffness of the upper plate of the lid structure is substantially greater than a stiffness of the lower plate of the lid structure that is bonded to the package structure. In one embodiment, the stiffness of the upper plate is substantially 2 to 10 times greater than the stiffness of the lower plate. In one embodiment, a thickness of the upper plate is substantially 2 to 5 times greater than a thickness of the lower plate. In one embodiment, the lid structure further comprises an inlet and an outlet in fluid communication with the fluid chamber, and a cooling fluid enters the fluid chamber through the inlet and leaves the fluid chamber through the outlet. In one embodiment, the plurality of spring members comprises a plurality of first spring members disposed in a center region of the fluid chamber and a plurality of second spring members surrounding the plurality of first spring members, and a spring constant of one of the plurality of first spring members is different from a spring constant of one of the plurality of second spring members. In one embodiment, the lid structure further comprises a plurality of fin structures disposed in the fluid chamber. In one embodiment, the semiconductor package further includes a thermal interface material disposed between the package structure and the lid structure. In one embodiment, the lid structure further comprises a sidewall portion connecting the fluid chamber and bonded to the substrate. In one embodiment, the semiconductor package further includes a ring structure bonded over the substrate and surrounding the package structure. In one embodiment, the ring structure is spaced apart from the lid structure.

In accordance with some embodiments of the disclosure, a semiconductor package includes a substrate, an interconnect structure bonded over the substrate, an encapsulated semiconductor device bonded over the interconnect structure, wherein the encapsulated semiconductor device comprises a semiconductor die encapsulated by an encapsulating material, and a lid structure bonded over the encapsulated semiconductor device and thermally coupled to the semiconductor die, wherein the lid structure includes a fluid chamber and a plurality of spring members in an array manner in the fluid chamber. In one embodiment, a stiffness of an upper plate of the lid structure is substantially greater than a stiffness of a lower plate of the lid structure that is bonded to the package structure. In one embodiment, a thickness of the upper plate is substantially greater than a thickness of the lower plate. In one embodiment, the semiconductor package further includes a package substrate, and the subtracted is bonded to the package substrate through a plurality of conductive connectors. In one embodiment, the lid structure further includes an inlet and an outlet in fluid communication with the fluid chamber, and a cooling fluid enters the fluid chamber through the inlet and leaves the fluid chamber through the outlet.

In accordance with some embodiments of the disclosure, a manufacturing method of a semiconductor package includes the following steps: bonding a semiconductor die over an interconnect structure; encapsulating the semiconductor die with an encapsulating material to form a package structure; bonding the package structure over a substrate; providing a thermal interface material over the package structure; bonding a lid structure over the substrate, wherein the lid structure is in contact with the thermal interface material and comprises a fluid chamber and a plurality of spring members disposed in the fluid chamber. In one embodiment, the lid structure further includes a lower plate and an upper plate, and bonding the lid structure over the substrate further includes: bonding the lower plate to the package structure through the thermal interface material; disposing the plurality of spring members over the lower plate; and bonding the upper plate over the lower plate and the plurality of spring members, wherein the upper plate and the lower plate jointly define the fluid chamber. In one embodiment, the lower plate is bonded to the substrate through an adhesive. In one embodiment, the manufacturing method of the semiconductor package further includes: bonding a ring structure over the substrate through an adhesive, wherein the ring structure is spaced apart from the lid structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a package structure bonded over the substrate; and
a lid structure bonded over the substrate and thermally coupled to the package structure, wherein the lid structure comprises a fluid chamber and a plurality of spring members disposed in the fluid chamber, wherein each of the plurality of spring members is connected between an upper plate and a lower plate of the lid structure.

2. The semiconductor package as claimed in claim 1, wherein a stiffness of the upper plate of the lid structure is substantially greater than a stiffness of the lower plate of the lid structure that is bonded to the package structure.

3. The semiconductor package as claimed in claim 2, wherein the stiffness of the upper plate is substantially 2 to10 times greater than the stiffness of the lower plate.

4. The semiconductor package as claimed in claim 1, wherein a thickness of the upper plate is substantially 2 to 5 times greater than a thickness of the lower plate.

5. The semiconductor package as claimed in claim 1, wherein the lid structure further comprises an inlet and an outlet in fluid communication with the fluid chamber, and a cooling fluid enters the fluid chamber through the inlet and leaves the fluid chamber through the outlet.

6. The semiconductor package as claimed in claim 1, wherein the plurality of spring members comprises a plurality of first spring members disposed in a center region of the fluid chamber and a plurality of second spring members surrounding the plurality of first spring members, and a spring constant of one of the plurality of first spring members is different from a spring constant of one of the plurality of second spring members.

7. The semiconductor package as claimed in claim 1, wherein the lid structure further comprises a plurality of fin structures disposed in the fluid chamber.

8. The semiconductor package as claimed in claim 1, further comprising a thermal interface material disposed between the package structure and the lid structure.

9. The semiconductor package as claimed in claim 1, wherein the lid structure further comprises a sidewall portion connecting the fluid chamber and bonded to the substrate.

10. The semiconductor package as claimed in claim 1, further comprising a ring structure bonded over the substrate and surrounding the package structure.

11. The semiconductor package as claimed in claim 10, wherein the ring structure is spaced apart from the lid structure.

12. A semiconductor package, comprising:
a substrate;
an interconnect structure bonded over the substrate;
an encapsulated semiconductor device bonded over the interconnect structure, wherein the encapsulated semiconductor device comprises a semiconductor die encapsulated by an encapsulating material; and
a lid structure bonded over the encapsulated semiconductor device and thermally coupled to the semiconductor die, wherein the lid structure comprises a fluid chamber and a plurality of spring members in an array manner in the fluid chamber.

13. The semiconductor package as claimed in claim 12, wherein a stiffness of an upper plate of the lid structure is substantially greater than a stiffness of a lower plate of the lid structure that is bonded to the package structure.

14. The semiconductor package as claimed in claim 13, wherein a thickness of the upper plate is substantially greater than a thickness of the lower plate.

15. The semiconductor package as claimed in claim 12, further comprising a package substrate, and the subtracted is bonded to the package substrate through a plurality of conductive connectors.

16. The semiconductor package as claimed in claim 12, wherein the lid structure further comprises an inlet and an outlet in fluid communication with the fluid chamber, and a cooling fluid enters the fluid chamber through the inlet and leaves the fluid chamber through the outlet.

17. A manufacturing method of a semiconductor package, comprising:
bonding a semiconductor die over an interconnect structure;
encapsulating the semiconductor die with an encapsulating material to form a package structure;
bonding the package structure over a substrate;
providing a thermal interface material over the package structure;
bonding a lid structure over the substrate, wherein the lid structure is in contact with the thermal interface material and comprises a fluid chamber and a plurality of spring members disposed in the fluid chamber.

18. The manufacturing method of the semiconductor package as claimed in claim 17, wherein the lid structure further comprises a lower plate and an upper plate, and bonding the lid structure over the substrate further comprises:
bonding the lower plate to the package structure through the thermal interface material;
disposing the plurality of spring members over the lower plate; and
bonding the upper plate over the lower plate and the plurality of spring members, wherein the upper plate and the lower plate jointly define the fluid chamber.

19. The manufacturing method of the semiconductor package as claimed in claim 18, wherein the lower plate is bonded to the substrate through an adhesive.

20. The manufacturing method of the semiconductor package as claimed in claim 18, further comprising:
bonding a ring structure over the substrate through an adhesive, wherein the ring structure is spaced apart from the lid structure.
